(19) United States
(12) Patent Application Publication
(10) Pub. No.: US 2008/0124854 A1
(43) Pub. Date: May 29, 2008

(54) METHOD FOR FABRICATING A SEMICONDUCTOR DEVICE AND A SEMICONDUCTOR DEVICE FABRICATED BY THE METHOD

(76) Inventors: Chel-Jong CHOI, Daejon (KR); Moon-Gyu JANG, Daejon (KR); Yark-Yeon KIM, Daejon (KR); Tae-Youb KIM, Seoul (KR); Myung-Sim JUN, Daejon (KR); Seong-Jae LEE, Daejon (KR)

Correspondence Address: LADAS & PARRY LLP, 224 SOUTH MICHIGAN AVENUE, SUITE 1600, CHICAGO, IL, 60604, US

(21) Appl. No.: 11/744,927

(22) Filed: May 7, 2007

(30) Foreign Application Priority Data
Nov. 29, 2006 (KR) 10-2006-0118985

(51) Int. Cl. H01L 29/76; H01L 21/8234

(52) U.S. Cl. 438/197; 257/288; 257/E29.226; 257/E21.616

(57) ABSTRACT

A method for fabricating a semiconductor device includes forming a gate insulation layer over a substrate, forming a conductive compound containing layer over the gate insulation layer, etching the conductive compound containing layer and the gate insulation layer to form a gate structure, forming a metal layer over the resultant structure obtained after the etching, and letting the metal layer to react with silicon from the substrate to form source and drain regions comprising a metal silicide layer over the substrate exposed on both sides of the gate structure, wherein the conductive compound containing layer does not react with the metal layer.

### CROSS-REFERENCES TO RELATED APPLICATIONS

The present invention claims priority of Korean patent application number 10-2006-0118985 filed on Nov. 29, 2006, which is incorporated by reference in its entirety.

### BACKGROUND OF THE INVENTION

The present invention relates to a method for fabricating a semiconductor device and a semiconductor device fabricated by the same method, more particularly, to a method for fabricating a semiconductor device based on a salicide process, and a semiconductor device fabricated by the same method.

The large-scale of integration in semiconductor devices leads to a great demand for devices with line widths of several tens of nanometers, for instance, sub-50 nm level. However, as the line width of a device decreases, the contact resistance and the sheet resistance generally affect operation characteristics of the device. A silicide process is one approach to reduce the effect of the contact and sheet resistance.

A silicide process is developed to form a stable metal compound by a reaction between silicon and metal. For instance, this silicide process is applied to gates, sources and drains of metal oxide semiconductor field effect transistors (MOSFETs), and to emitters, bases, and collectors of bipolar transistors. The silicide process is advantageous of reducing the sheet and contact resistance at contact areas, so as to implement high-performance devices.

The silicide process is further developed to a self-aligned silicide process, so called “salicide process” in which silicide is formed selectively on gates, sources and drains of transistors based on a self-aligning method. This salicide process is considered essential for a semiconductor fabrication technology.

In general, spacers need to be formed on sidewalls of a gate structure in order for the salicide process to be implemented to the semiconductor fabrication technology. Such spacers are commonly formed of an oxide or nitride material, and formed through performing a dry etching process.

One exemplary salicide process with the implementation of spacers is described in Korean Patent No. 0135163 issued to J. S. Peon and J. J. Kim on Jan. 12, 1998 in the name of “Method for Fabrication MOS Transistor with Shallow Source/Drain Junctions and Silicide.” In this Korean Patent document, spacers are formed on sidewalls of a gate structure, and a metal layer is deposited to a certain thickness on the resultant structure. When a thermal treatment is applied to the resultant structure, silicide is formed on the gate structure and source/drain regions where silicon is exposed, but not on the spacers. The metal layer formed on the upper surface of the spacers is removed by a wet etching process.

However, in the salicide process with the implementation of the spacers, the dry etching for forming the spacers may induce some limitations in upper portions of the source/drain regions, and produce an under-cut underneath the spacers. As a result, leakage current and a threshold voltage level are likely to increase, and thus, operation characteristics of devices may be degraded.

In Korean Patent No. 0477535 issued to T. W. Kim on Mar. 9, 2005 in the name of “Method of Manufacturing Semiconductor Device,” another approach to the conventional salicide process is suggested to overcome the limitations associated with the dry etching. An oxide layer is formed as first spacers on both sidewalls of a gate structure, and a stack structure, which includes a first oxide layer, a nitride layer and a second oxide layer in sequence, is formed as second spacers on the first spacers.

Another approach to the conventional process to overcome the aforementioned limitations is taught in Korean Patent No. 0519518 issued to Y. T. Kim on Sep. 28, 2005, entitled “Method for Forming Gate Spacer.” A gate structure including a gate oxide layer, a polysilicon layer, and a tungsten silicide layer is formed, and oxygen (O₂) ion implantation and oxidation are performed on the surface of a silicon-based substrate, exposed on both sides of the gate structure, so that a silicon oxide layer is formed more thickly on the surface of the silicon-based substrate than on the sidewalls of the gate structure. This silicon oxide layer functions as a protection layer against a dry etching for forming spacers. Due to the silicon oxide layer, the silicon-based substrate is less likely to be damaged or recessed.

However, since the above suggested approaches commonly accompany the dry etching to form the spacers on the sidewalls of the gate structure, it may be difficult to prevent the induction of some limitations associated with the dry etching (e.g., damaged source/drain regions). Furthermore, the spacers are usually formed by additionally performing deposition and etching processes, and thus, resulting in complicated fabrication processes.

### SUMMARY OF THE INVENTION

Specific embodiments of the present invention are directed toward providing a method for fabricating a semiconductor device capable of simplifying fabrication processes and reducing damages to source and drain regions.

Specific embodiments of the present invention are directed toward providing a semiconductor device fabricated by the method allowing the simplification of the fabrication processes and disallowing the damages to the source and drain regions.

In accordance with one aspect of the present invention, there is provided a method for fabricating a semiconductor device. The method includes forming a gate insulation layer over a substrate, forming a conductive compound containing layer over the gate insulation layer, etching the conductive compound containing layer and the gate insulation layer to form a gate structure, forming a metal layer over the resultant structure obtained after the etching, and letting the metal layer to react with silicon from the substrate to form source and drain regions including a metal silicide layer over the substrate exposed on both sides of the gate structure, wherein the conductive compound containing layer does not react with the metal layer.

In accordance with another embodiment of the present invention, there is provided a method for fabricating a semiconductor device. The method includes forming a gate insulation layer over a substrate, forming a conductive compound containing layer over the gate insulation layer, etching the conductive compound containing layer and the gate insulation layer to form a gate structure, forming source and drain regions in the substrate exposed on both sides of the gate structure, forming a metal layer over the substrate including the source and drain regions, and forming a metal silicide layer through a reaction between the metal layer and silicon from the source and drain regions, wherein the conductive compound containing layer does not reaction with the metal layer.

In accordance with another embodiment of the present invention, there is provided a semiconductor device, including a gate insulation layer formed over a substrate, a gate structure formed over the gate insulation layer and including a conductive compound that does not react with a subsequent metal layer, and source and drain regions formed in the substrate exposed on both sides of the gate structure and including a metal silicide layer formed through a reaction between the metal layer and silicon from the substrate.

In accordance with another embodiment of the present invention, there is provided a semiconductor device, including a gate insulation layer, a gate structure formed over the gate insulation layer and including a conductive compound that does not react with a subsequent metal layer, source and drain regions formed in the substrate exposed on both sides of the gate structure, and a metal silicide layer formed over the source and drain regions through a reaction between the metal layer and silicon from the source and drain regions.

### BRIEF DESCRIPTION OF THE DRAWINGS

FIGS. 1A to 1E illustrate a method for fabricating a semiconductor device in accordance with an embodiment of the present invention.

FIG. 2 illustrates a graph of gate voltage versus capacitance of a gate capacitor provided by a fabrication method of a semiconductor device in accordance with an embodiment of the present invention.

FIG. 3 illustrates a high-resolution transmission electron microscopic image of a gate capacitor provided by a fabrication method of a semiconductor device in accordance with an embodiment of the present invention.

FIG. 4 illustrates a scanning electron microscopic image of an N-type Schottky barrier (SB) MOSFET provided by a fabrication method of a semiconductor device in accordance with an embodiment of the present invention.

FIGS. 5A and 5B are graphs for illustrating operation characteristics of the SB MOSFET illustrated in FIG. 4.

### DESCRIPTION OF SPECIFIC EMBODIMENTS

Various embodiments of the present invention are directed toward a method for fabricating a semiconductor device allowing the implementation of a salicide process without forming spacers on sidewalls of a gate structure. In particular, semiconductor devices fabricated by the method according to various embodiments of the present invention include MOSFETs, more specifically, SB MOSFETs.

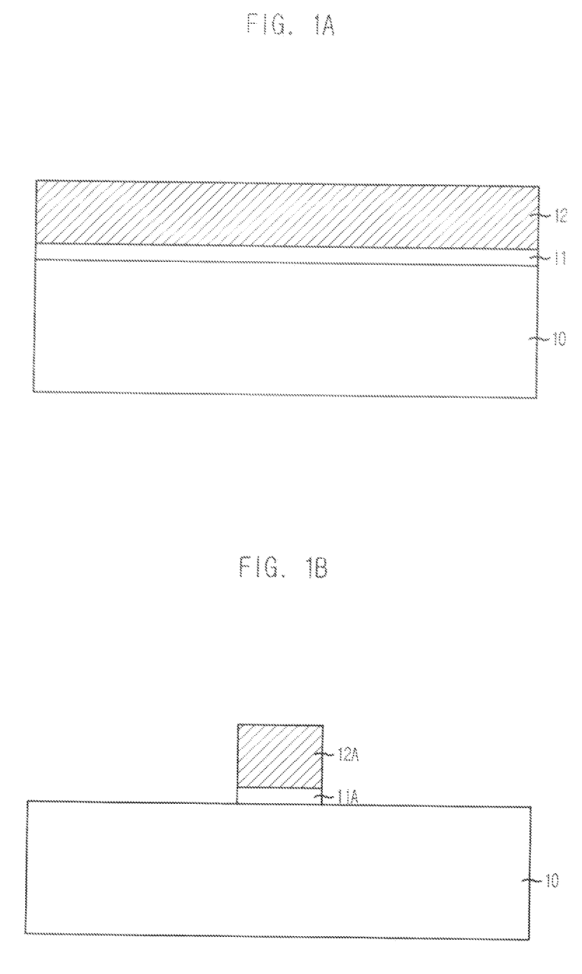

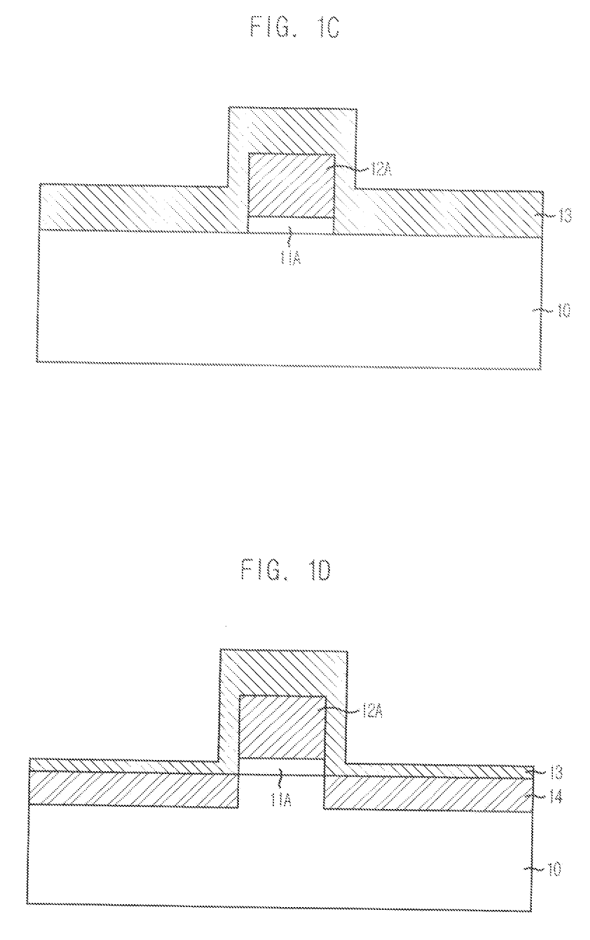

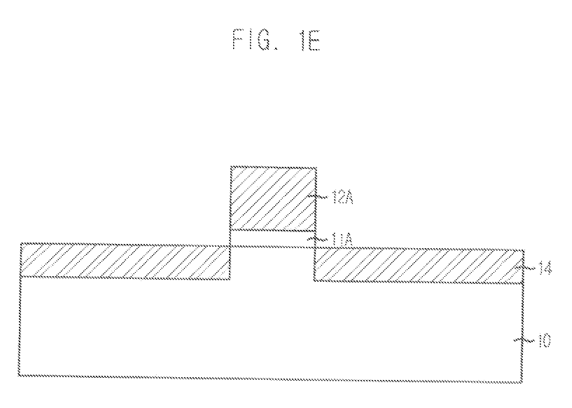

FIGS. 1A to 1E illustrate a method for fabricating a semiconductor device in accordance with an embodiment of the present invention. In particular, a fabrication method of a SB MOSFET is exemplified in the present embodiment. Also, in the drawings, the thickness of layers and regions are exaggerated for clarity of the description, and when it is described that one layer is formed on another layer or a substrate, the term “on” indicates that the layer may be formed directly on the other layer or the substrate, or a third layer may be interposed therebetween.

Referring to FIG. 1A, a gate insulation layer 11 is formed over a substrate 10. Although the substrate 10 may include a single crystalline silicon containing substrate, the substrate 10 may include a substrate containing a silicon based material such as polycrystalline silicon, amorphous silicon, silicon germanium (SiₓGe₁₋ₓ, where 0<x<1), silicon nitride (SiₓN₁₋ₓ, where 0<x<1), or silicon carbide (SiC). The gate insulation layer 11 may be an oxide-based layer, an interposition layer in which a nitride-based layer is interposed between oxide-based layers, or a metal oxide layer whose dielectric constant is greater than silicon dioxide (SiO₂). For instance, the metal oxide layer may include hafnium dioxide (HfO₂), aluminum oxide (Al₂O₃), or zirconium dioxide (ZrO₂). If the gate insulation layer 11 is an oxide-based layer, a wet oxidation, dry oxidation or radical oxidation may be performed.

A conductive layer 12 for use in a gate is formed over the gate insulation layer 11. The conductive layer 12 includes a conductive compound selected from a group consisting of zinc oxide (ZnO), tin oxide (SnO₂), indium tin oxide (ITO), and gallium nitride (GaN). The conductive compound-based conductive layer 12 is formed by performing a sputtering method, an electron beam evaporation method, a chemical vapor deposition (CVD) method, a physical vapor deposition (PVD) method, a metal-organic chemical vapor deposition (MOCVD), or a molecular beam epitaxy (MBE) method. In addition to the aforementioned methods, other various methods can be used to deposit the conductive compound.

Referring to FIG. 1B, although not illustrated, a photoresist layer is coated over the conductive layer 12, and exposed to light and developed using a photo-mask to form a photoresist pattern. The conductive layer 12 and the gate insulation layer 11 (see FIG. 1A) are etched using the photoresist pattern as an etch mask. This etching may be a wet etching or a dry etching. After this etching, a gate electrode 12A and a gate insulation pattern 11A are formed.

The photoresist pattern is removed. A cleaning treatment may be performed on the resultant structure including the substrate 10, the gate insulation pattern 11A and the gate electrode 12A. The cleaning treatment may proceed with using a buffered oxide etchant (BOE) or diluted hydrogen fluoride (DHF) to remove a native oxide layer (not illustrated), which may be formed on the surface of the substrate 10. The BOE is a mixture solution including HF and ammonium fluoride (NH₄F), and the DHF is a HF solution diluted with water (H₂O).

Referring to FIG. 1C, a metal layer 13 is formed over the surface of the resultant structure illustrated in FIG. 1B. The metal layer 13 includes a transition metal or a rare earth metal. For instance, the metal layer 13 includes one selected from a group consisting of cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), nickel (Ni), titanium (Ti), cobalt (Co), copper (Cu), platinum (Pt), tungsten (W), chromium (Cr), molybdenum (Mo), gold (Au), silver (Ag), zinc (Zn), iridium (Ir), tantalum (Ta), hafnium (Hf), potassium (K), lithium (Li), cesium (Cs), and alloys thereof. The metal layer 13 may include a compound bound to nitrogen or oxygen. Also, the metal layer 13 may be formed to a thickness of about 1,000 nm or less. If the thickness of the metal layer 13 is greater than about 1,000 nm, a metal silicide layer is often formed overly over source and drain regions. As a result, the source and drain regions are likely to contact with each other underneath a gate structure, and thus, a short circuit event may occur.

Referring to FIG. 1D, the metal layer 13 reacts with silicon from the substrate 10 by a thermal treatment, and as a result, source and drain regions 14 are formed in the substrate 10 exposed on both sides of the gate electrode 12A. The source and drain regions 14 include a metal silicide layer. The thermal treatment provides heat to allow the metal layer 13 to react with the silicon from the substrate 10, and may include a rapid thermal annealing, a furnace annealing, or a laser annealing.

The thermal treatment is performed at a certain temperature selected depending on types and characteristics of the metal silicide layer desired to be formed. For instance, if the desired metal silicide layer includes ErSi_{1.7}, the thermal treatment is performed at about 300° C. or higher because an ErSi_{1.7} layer is less likely to be formed if the thermal treatment is performed at a temperature less than about 300° C. Referring to FIG. 1E, a remaining portion of the metal layer 13 that does not react with the silicon from the substrate 10 is removed.

Although the present embodiment describes a method for fabricating a SB MOSFET, the embodied method can also be implemented to a method for fabricating a MOSFET, and this fabrication method of the MOSFET will be described herein below. In the following drawings, like reference numerals represent like elements described in FIGS. 1A to 1E.

As described in the above exemplified embodiment, those treatments implemented in FIGS. 1A and 1B are performed. Although not illustrated, an ion implantation for lightly doped drains (LDDS) is performed to form lightly doped junction regions in the substrate 10 exposed on both sides of the gate electrode 12A. Afterwards, an ion implantation for highly doped drains is performed to form source and drain regions, which are deeper and more highly doped than the lowly doped junction regions.

As similar to FIG. 1C, a metal layer 13 is formed over the surface of the resultant structure obtained after forming the source and drain regions, and a thermal treatment is performed on the metal layer 13 to form a metal silicide layer over the source and drain regions. As similar to FIG. 1D, a remaining portion of the metal layer 13 that does not react with silicon from the substrate 10 is removed.

In the above described embodiments, the gate electrode is formed based on a conductive compound that does not react with the metal layer, and thus, during the silicide process for forming the source and drain regions, the metal layer reacts with silicon from the substrate selectively in the source and drain regions, so as to form the metal silicide layer thereon. Hence, different from the conventional silicide process, spacers do not need to be formed additionally on the sidewalls of the gate electrode.

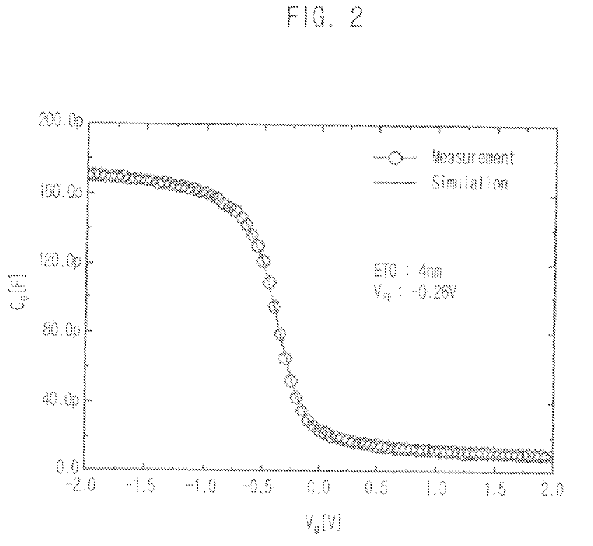

Operation characteristics of the semiconductor device fabricated by the method described in the above embodiments will be described herein below. FIG. 2 illustrates a graph of gate voltage versus capacitance of a gate capacitor provided by a method, which includes forming an indium tin oxide (ITO) layer, which is one of conductive compounds, as a gate electrode material over a gate insulation layer (e.g., an oxide-based layer including SiO₂), and etching the ITO layer. The gate insulation layer was formed to a thickness of about 4 nm, and the ITO layer was formed to a thickness of about 100 nm. On the basis of the simulation result obtained in consideration of the Quantum effect as shown in FIG. 2, an equivalent oxide thickness (EOT) and a feedback voltage V_{FB} were measured at about 40 nm and −0.26 V, respectively. The simulation result and the experimental result were concordant with each other. Based on this fact, the gate capacitor including the ITO layer operated normally.

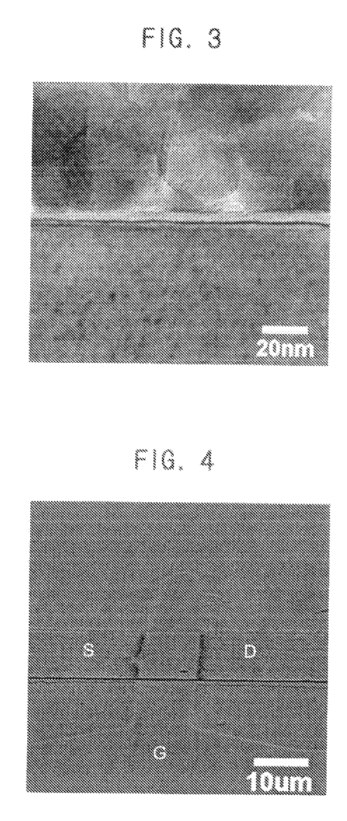

FIG. 3 illustrates a high-resolution transmission electron microscopic image of the gate capacitor illustrated in FIG. 2. Referring to FIG. 3, a SiO₂ layer was formed uniformly in an amorphous state over a silicon-based substrate. The SiO₂ layer formed as a gate insulation layer had a thickness of about 4 nm. Also, ITO composed of small grains having an average size of about 21 nm was formed uniformly in a polycrystalline state over the SiO₂ layer. As shown in FIG. 3, the ITO did not penetrate into the bottom of the SiO₂ layer.

FIG. 4 illustrates a scanning electron microscopic image of an N-type SB MOSFET including a gate electrode formed of ITO in accordance with an embodiment of the present invention. The gate electrode was formed to have a length and a width each of about 10 μm, and a metal layer was formed of Er. A thermal treatment was performed at about 500° C. for about 3 minutes, so that an ErSi_{1.7} layer was selectively formed over source and drain regions. A remaining portion of the metal layer was removed by a wet etching.

As illustrated in FIG. 4, a metal silicide layer or a metal layer did not exist on the sidewalls or the surface of the gate electrode including ITO. This result indicates that Er from the metal layer remained as pure Er instead of reacting with ITO from the gate electrode during the thermal treatment, and removed by the wet etching.

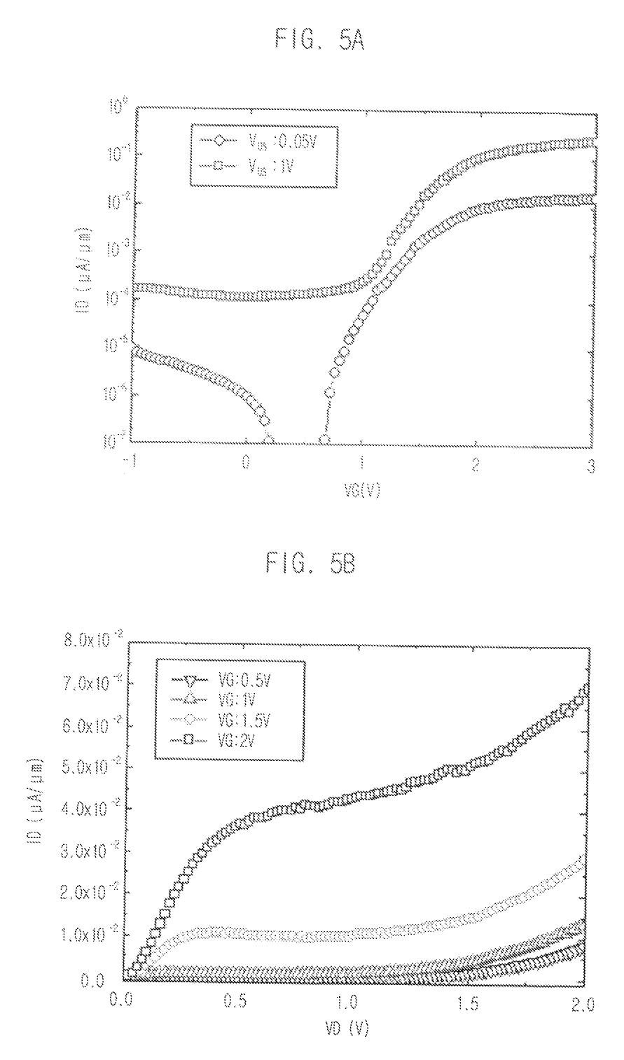

FIGS. 5A and 5B are graphs illustrating operation characteristics of an N-type SB MOSFET including a gate electrode formed of ITO in accordance with an embodiment of the present invention. In particular, FIG. 5A illustrates a graph of gate voltage labeled as “VG” versus terminal current labeled as “ID,” and FIG. 5B illustrates a graph of terminal voltage labeled as “VD” versus terminal current labeled as “ID.” An ErSi_{1.7} layer was formed as source and drain regions of the N-type SB MOSFET, and a gate insulation layer was formed of an oxide-based material such as SiO₂. A material such as ITO was used to form a gate electrode.

Referring to FIG. 5A, as the gate voltage VG increased from a negative value to a positive value, the terminal current ID increased abruptly. Referring to FIG. 5B, as the gate voltage VG and the terminal voltage VD increased to a certain level, the terminal current ID increased abruptly. From these results, the N-type SB MOSFET fabricated based on the embodied method operated appropriately.

According to various embodiments of the present invention, a conductive compound is used to form the gate electrode. Thus, a semiconductor device implemented with metal silicide without additional spacers can be fabricated. Also, high-performance and high-quality semiconductor devices can be fabricated with cost-effectiveness.

Although the scope and sprit of the present invention are described in detail based on various embodiments, these embodiments are provided for clear understanding of the present invention, and thus, should not be construed as limiting the scope and sprit of the present invention. In particular, the exemplary embodiments are mainly focused on SB MOSFETs, these embodiments can still be applied to any semiconductor device including source and drain regions formed through a salicide process, for instance, a complementary metal oxide semiconductor (CMOS) logic device, a volatile memory device, a non-volatile memory device, or an embedded memory device.

While the present invention has been described with respect to specific embodiments, it will be apparent to those skilled in the art that various changes and modifications may be made without departing from the spirit and scope of the invention as defined in the following claims.

What is claimed is:

1. A method for fabricating a semiconductor device, the method comprising:
forming a gate insulation layer over a substrate;
forming a conductive compound containing layer over the gate insulation layer;
etching the conductive compound containing layer and the gate insulation layer to form a gate structure;
forming a metal layer over the resultant structure obtained after the etching; and
letting the metal layer to react with silicon from the substrate to form source and drain regions comprising a metal silicide layer over the substrate exposed on both sides of the gate structure,
wherein the conductive compound containing layer does not react with the metal layer.

2. The method of claim 1, further comprising, after forming the source and drain regions including the metal silicide layer, removing a remaining portion of the metal layer that does not react with the silicon from the substrate.

3. The method of claim 1, wherein the substrate comprises one selected from a group consisting of single crystalline silicon, polycrystalline silicon, amorphous silicon, silicon germanium (SiₓGe₁₋ₓ), where 0<x<1, Silicon nitride (SiₓN₁₋ₓ), where 0<x<1, and silicon carbide (SiC).

4. The method of claim 1, wherein the conductive compound comprises one selected from a group consisting of zinc oxide, tin oxide, indium tin oxide, and gallium nitride.

5. The method of claim 1, wherein the conductive compound containing layer is formed using one of a sputtering method, an electron beam evaporation method, a chemical vapor deposition method, a physical vapor deposition method, a metal-organic chemical vapor deposition method, and a molecular beam epitaxy method.

6. The method of claim 1, wherein the metal layer comprises one selected from a group consisting of cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), nickel (Ni), titanium (Ti), cobalt (Co), copper (Cu), platinum (Pt), tungsten (W), chromium (Cr), molybdenum (Mo), gold (Au), silver (Ag), zinc (Zn), iridium (Ir), tantalum (Ta), hafnium (Hf), potassium (K), lithium (Li), cesium (Cs), and alloys thereof.

7. The method of claim 1, wherein the metal layer comprises a compound bound to nitrogen or oxygen.

8. The method of claim 1, wherein the metal silicide layer is formed by performing a thermal treatment.

9. A method for fabricating a semiconductor device, the method comprising:
forming a gate insulation layer over a substrate;
forming a conductive compound containing layer over the gate insulation layer;
etching the conductive compound containing layer and the gate insulation layer to form a gate structure;
forming source and drain regions in the substrate exposed on both sides of the gate structure;
forming a metal layer over the substrate including the source and drain regions; and
forming a metal silicide layer through a reaction between the metal layer and silicon from the source and drain regions,
wherein the conductive compound containing layer does not reaction with the metal layer.

10. The method of claim 9, further comprising, after forming the metal silicide layer, removing a remaining portion of the metal layer that does not react with the silicon.

11. The method of claim 9, wherein the substrate comprises one selected from a group consisting of single crystalline silicon, polycrystalline silicon, amorphous silicon, silicon germanium (SiₓGe₁₋ₓ), where 0<x<1, Silicon nitride (SiₓN₁₋ₓ), where 0<x<1, and silicon carbide (SiC).

12. The method of claim 9, wherein the conductive compound comprises one selected from a group consisting of zinc oxide, tin oxide, indium tin oxide, and gallium nitride.

13. The method of claim 9, wherein the conductive compound containing layer is formed using one of a sputtering method, an electron beam evaporation method, a chemical vapor deposition method, a physical vapor deposition method, a metal-organic chemical vapor deposition method, and a molecular beam epitaxy method.

14. The method of claim 9, wherein the metal layer comprises one selected from a group consisting of cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), nickel (Ni), titanium (Ti), cobalt (Co), copper (Cu), platinum (Pt), tungsten (W), chromium (Cr), molybdenum (Mo), gold (Au), silver (Ag), zinc (Zn), iridium (Ir), tantalum (Ta), hafnium (Hf), potassium (K), lithium (Li), cesium (Cs), and alloys thereof.

15. The method of claim 9, wherein the metal layer comprises a compound bound to nitrogen or oxygen.

16. The method of claim 9, wherein the metal silicide layer is formed by performing a thermal treatment.

17. A semiconductor device, comprising:
a gate insulation layer formed over a substrate;
a gate structure formed over the gate insulation layer and comprising a conductive compound that does not react with a subsequent metal layer; and
source and drain regions formed in the substrate exposed on both sides of the gate structure and comprising a metal silicide layer formed through a reaction between the metal layer and silicon from the substrate.

18. The method of claim 17, wherein the substrate comprises one selected from a group consisting of single crystalline silicon, polycrystalline silicon, amorphous silicon, silicon germanium (SiₓGe₁₋ₓ), where 0<x<1, Silicon nitride (SiₓN₁₋ₓ), where 0<x<1, and silicon carbide (SiC).

19. The method of claim 17, wherein the conductive compound comprises one selected from a group consisting of zinc oxide, tin oxide, indium tin oxide, and gallium nitride.

20. The method of claim 17, wherein the metal layer comprises one selected from a group consisting of cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), nickel (Ni), titanium (Ti), cobalt (Co), copper (Cu), platinum (Pt), tungsten (W), chromium (Cr), molybdenum (Mo), gold (Au), silver (Ag), zinc (Zn), iridium (Ir), tantalum (Ta), hafnium (Hf), potassium (K), lithium (Li), cesium (Cs), and alloys thereof.

21. The method of claim 17, wherein the metal layer comprises a compound bound to nitrogen or oxygen.

22. A semiconductor device, comprising:
a gate insulation layer;
a gate structure formed over the gate insulation layer and comprising a conductive compound that does not react with a subsequent metal layer;
source and drain regions formed in the substrate exposed on both sides of the gate structure; and
a metal silicide layer formed over the source and drain regions through a reaction between the metal layer and silicon from the source and drain regions.

23. The method of claim 22, wherein the substrate comprises one selected from a group consisting of single crystalline silicon, polycrystalline silicon, amorphous silicon, silicon germanium (SiₓGe₁₋ₓ), where 0<x<1, Silicon nitride (SiₓN₁₋ₓ), where 0<x<1, and silicon carbide (SiC).

24. The method of claim 22, wherein the conductive compound comprises one selected from a group consisting of zinc oxide, tin oxide, indium tin oxide, and gallium nitride.

25. The method of claim 22, wherein the metal layer comprises one selected from a group consisting of cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), nickel (Ni), titanium (Ti), cobalt (Co), copper (Cu), platinum (Pt), tungsten (W), chromium (Cr), molybdenum (Mo), gold (Au), silver (Ag), zinc (Zn), iridium (Ir), tantalum (Ta), hafnium (Hf), potassium (K), lithium (Li), cesium (Cs), and alloys thereof.

26. The method of claim 22, wherein the metal layer comprises a compound bound to nitrogen or oxygen.
